(19) United States
(12) Patent Application Publication
(10) Pub. No.: US 2016/0093491 A1
(43) Pub. Date: Mar. 31, 2016

(54) LARGE SCALE AND THICKNESS-MODULATED MoS2 NANOSHEETS

(71) Applicant: University of North Texas, Denton, TX (US)

(72) Inventors: Wonbong Choi, Dallas, TX (US); Nitin Choudhary, Denton, TX (US)

(21) Appl. No.: 14/868,428

(22) Filed: Sep. 29, 2015

Related U.S. Application Data
(60) Provisional application No. 62/056,751, filed on Sep. 29, 2014.

(51) Int. Cl. H01L 21/02; H01L 29/786; H01L 29/66

(52) U.S. Cl. CPC H01L 21/02568; H01L 29/66969; H01L 29/786; H01L 21/02631

(57) ABSTRACT

The invention is for fabricating large-area, thickness-modulated MoS₂, varying from single to few layer MoS₂ films on various substrates using a combination of magnetron sputtering followed by chemical vapor deposition. The thickness dependent energy bandgap engineering and surface induced polarity change is disclosed.

### CROSS-REFERENCE TO RELATED APPLICATIONS

This application claims priority based on U.S. Provisional Application No. 62/056,751, filed Sep. 29, 2014. The contents of which is incorporated by reference in its entirety.

### TECHNICAL FIELD OF THE INVENTION

The present invention relates in general to the field of thin film formation, and more particularly, to fabricating large-area, thickness-modulated MoS₂ films on various substrates.

### STATEMENT OF FEDERALLY FUNDED RESEARCH

None.

### INCORPORATION-BY-REFERENCE OF MATERIALS FILED ON COMPACT DISC

None.

### BACKGROUND OF THE INVENTION

Without limiting the scope of the invention, its background is described in connection with modulating the thickness of MoS₂ films on various substrates and FET devices using the same. U.S. Pat. No. 4,536,943, entitled “Method of manufacturing a FET,” discloses a method of forming electrodes or wiring structures in a semiconductor device, metal and metal silicide are used for electrodes and lead wires, impurities are doped into the interface of a semiconductor substrate from the surface by gas diffusion or solid diffusion irrespective of the thickness, and in the case where the base material is an insulating material, the impurities are not doped into the semiconductor region side by self-alignment. The entire contents of which are incorporated herein by reference.

U.S. Patent Application Publication No. 2012/0280235, entitled “Thin film FET device and, method for forming the same” discloses a thin film FET device and a method of forming the same. The method comprises: etching a single crystal silicon thin film layer on an insulating thin film layer of an SOI substrate, wherein the etched single crystal silicon thin film layer is used as a channel; forming a gate insulating layer on the SOI substrate that has the single crystal silicon channel formed thereon; and forming a gate electrode, a drain electrode, and a source electrode. The entire contents of which are incorporated herein by reference.

### SUMMARY OF THE INVENTION

The invention is for fabricating large-area, thickness-modulated MoS₂, varying from single to few layer MoS₂ films on various substrates using a combination of magnetron sputtering followed by chemical vapor deposition. The thickness dependent energy bandgap engineering and surface induced polarity change is disclosed.

The present invention provides a method of making a thin layer MoS₂ on a substrate comprising the steps of: providing a substrate; providing a Molybdenum source; using a magnetron to induce a plasma to generate Molybdenum ions; sputtering the Molybdenum ions on the substrate to form a thin layer of Molybdenum; placing the substrate in a CVD chamber; providing a sulphur source; forming a sulphur vapor in communication with the CVD chamber; and sulphurizing the thin layer of Molybdenum to form a thin layer of Molybdenum disulfide.

The present invention provides a method of making a thin layer transition metal dichalcogenide (MX₂) on a substrate comprising the steps of: providing a substrate; providing a transition metal source; using a magnetron to induce a plasma to generate transition metal ions; sputtering the transition metal ions on the substrate to form a thin layer of transition metal; placing the substrate in a CVD chamber; providing a chalcogen source; forming a chalcogen vapor in communication with the CVD chamber; and contacting the chalcogen vapor with the thin layer of transition metal to form a thin layer of transition metal dichalcogenide. The transition metal may be Mo, W, or Nb. The chalcogen may be S, Se, or Te. The method of claim 2, wherein the transition metal dichalcogenide is MoS₂, MoSe₂, MoTe, WS₂, WSe₂, WTe, NbS₂, NbSe₂, or NbTe. The thin layer of transition metal may be 1, 2, 3, 4, 5, 6, 7, 8, 9, 10, 11, 12, 13, 14, 15, 16, 17, 18, 19, 20, 21, 22, 23, 24, 25, 26, 27, 28, 29, 30 or more layers thick. The transition metal dichalcogenide may be 1, 2, 3, 4, 5, 6, 7, 8, 9, 10, 11, 12, 13, 14, 15, 16, 17, 18, 19, 20, 21, 22, 23, 24, 25, 26, 27, 28, 29, 30 or more layers thick. The method may further comprise the step of controlling one or more parameters of the magnetron sputtering to apply 2, 3, 4, 5, 6, 7, 8, 9, 10, 11, 12, 13, 14, 15, 16, 17, 18, 19, 20, 21, 22, 23, 24, 25, 26, 27, 28, 29, 30 or more layers of the transition metal. The method may further comprise the step of adding a second transition metal to form a second thin layer on the thin layer. The transition metal and the second transition metal may be different. The substrate may be a Si/SiO₂ substrate. The magnetron sputtering may use a RF power source to creating plasma. The temperature of the substrate is at a temperature of between room temperature −800° C.

The present invention provides a method of thickness dependent energy bandgap by controlling thin layer transition metal dichalcogenide (MX₂) thickness on a substrate comprising the steps of: providing a substrate; providing a transition metal source; using a magnetron to induce a plasma to generate transition metal ions; sputtering the transition metal ions on the substrate to form a thin layer of transition metal; placing the substrate in a CVD chamber; providing a chalcogen source; forming a chalcogen vapor in communication with the CVD chamber; and contacting the chalcogen vapor with the thin layer of transition metal to form a thin layer of transition metal dichalcogenide. The transition metal may be Mo, W, or Nb and the chalcogen is S, Se, or Te.

The present invention provides a method of forming a thin film field effect transistor (FET) device, comprising: providing a silicon-on-insulator substrate; etching a single crystal silicon thin film layer on an insulating thin film layer of the silicon-on-insulator substrate, wherein the etched single crystal silicon thin film layer is used as a channel; forming a gate insulating layer on the silicon-on-insulator substrate that has the single crystal silicon channel formed thereon; and forming a gate electrode, a drain electrode, and a source electrode by providing a substrate; providing a transition metal source; using a magnetron to induce a plasma to generate transition metal ions; sputtering the transition metal ions on the substrate to form a thin layer of transition metal; placing the substrate in a CVD chamber; providing a chalcogen source; forming a chalcogen vapor in communication with the CVD chamber; and contacting the chalcogen vapor with the thin layer of transition metal to form a thin layer of transition metal dichalcogenide. The transition metal may be Mo, W, or Nb and the chalcogen is S, Se, or Te.

### BRIEF DESCRIPTION OF THE DRAWINGS

For a more complete understanding of the features and advantages of the present invention, reference is now made to the detailed description of the invention along with the accompanying figures and in which:

FIG. 1a is an image of the first step of sputtering followed by the second step of CVD method for the growth of MoS₂ thin films seen in FIG. 1b. FIG. 1c is an optical image of large area MoS₂ growth on a Si/SiO₂ substrate and FIG. 1d is an optical image of large area MoS₂ growth on a transparent substrate. FIG. 1e is an image showing the Optical contrast of MoS₂ films at for sample S1-S5 shows different thicknesses.

FIG. 2a is a graph of Mo and MoS₂ film thickness for sample S1-S5. FIG. 2b is an image of the AFM height profiles and images of a Mo and MoS₂ film on a Si/SiO₂ substrate of sample S1.

FIG. 3a is an image of the Raman spectra of MoS₂ thin films corresponding to sample S1, S2, S3, S4 and S5. FIG. 3b is an image of the difference between the in-plane (E¹₂g) and out-of-plane (A_{1g}) Raman modes (Δk) with increasing MoS₂ film thickness: Inset shows the raman peak FWHM of E12g and A1_{g} modes. FIG. 3c is a cross-sectional HRTEM image of sample S1. FIG. 3d is a cross-sectional HRTEM image of sample S2.

FIG. 4a is a Raman mapping images of E¹_{2g} frequencies for a 150 μm×150 μm area for sample S1. FIG. 4b is a Raman mapping images of A_{1g} frequencies for a 150 μm×150 μm area for sample S1. FIG. 4c is a schematic of layer and island growth mechanism in sputtered Mo films.

FIG. 5a is a 3D view of the MoS₂ FET. FIG. 5b is a graph of the room-temperature output (I_{d}-V_{d}) characteristics for sample S2 as a function of gate bias V_{g} from 0 to −15V. FIG. 5c is a graph of the drain-source current I_{d} as a function of backgate voltage Vg at fixed V_{d}=500 mV with linear-fit of the data to calculate field effect mobility. Inset shows the I_{d}-V_{g} curve plotted in logarithmic scale as a function of back-gate voltage V_{g} at fixed V_{d}=500 mV.

FIG. 6 is a schematic band diagram of SiO₂/MoS₂ interface showing the formation of acceptor level above Fermi level due to the presence of impurities, dangling bonds at the interface.

FIG. 7 shows the band gap variations from an indirect (bulk) to direct (SL) TMDs with decreasing thickness.

FIG. 8 shows MoSe₂/WSe₂, MoS₂/graphene and MoS₂/WS₂ hetero junctions.

FIG. 9 shows a large scale MoS₂ lubricant coating on curved surfaces, e.g., spherical or cylindrical objects.

### DETAILED DESCRIPTION OF THE INVENTION

While the making and using of various embodiments of the present invention are discussed in detail below, it should be appreciated that the present invention provides many applicable inventive concepts that can be embodied in a wide variety of specific contexts. The specific embodiments discussed herein are merely illustrative of specific ways to make and use the invention and do not delimit the scope of the invention.

To facilitate the understanding of this invention, a number of terms are defined below. Terms defined herein have meanings as commonly understood by a person of ordinary skill in the areas relevant to the present invention. Terms such as “a”, “an” and “the” are not intended to refer to only a singular entity, but include the general class of which a specific example may be used for illustration. The terminology herein is used to describe specific embodiments of the invention, but their usage does not delimit the invention, except as outlined in the claims.

The present invention provides for fabricating large-area, thickness-modulated MoS₂, varying from single to few layer MoS₂ films on various substrates using a combination of magnetron sputtering followed by chemical vapor deposition. The present invention provides a method that includes a two-step sputtering-CVD reaction approach that produce high quality, large scale and thickness modulated MoS₂ atomic layers over a large area of Si/SiO₂ substrate. Mo thin film thickness can be varied by changing magnetron sputtering parameter to modulate the thickness of MoS₂ film via sulfurization. The presence of single layers over a wafer was confirmed by Raman mapping AFM and HRTEM images. Electrical measurements demonstrated high mobility and on/off ratio as compared to exfoliated and other CVD grown MoS₂ films on silicon substrates.

In recent years, 2D materials like graphene and transition metal dichalcogenides (TMDs) are gaining a wealth of attention from the scientific community and industry for being the promising materials for next-generation ultrathin electronic and optoelectronic devices. The most interesting feature of these materials is that the bulk of these materials are composed of layered structures with strong covalent bonding within each layer and weak van der Waals forces between the adjacent layers. Therefore, single or few-layer nanosheets of these materials can be obtained by using mechanical exfoliation using adhesive tapes. Graphene, while being fundamentally and technologically interesting for a variety of applications with remarkable electronic properties, e.g., its massless Dirac fermions has an effective speed of light vF≈10⁶ ms⁻¹ and a room temperature mobility of 200,000 cm²V⁻¹s⁻¹ in addition to its flexibility and high transparency. However, the absence of band gap in graphene leading to a very low Ion/off ratio limits its broader use for applications in electronics like logic devices. With this consideration, TMDs, in particular, molybdenum disulphide (MoS₂) has recently emerged as a great alternative to graphene that offers a better solution of fabricating high performance electronic devices as they are intrinsic semiconductors and possesses unique properties of quantum confinement and thickness-dependent band gap i.e., changing from 1.3 eV to 1.9 eV for bulk (indirect bandgap) and single layer (direct bandgap) MoS₂, respectively. Therefore, MoS₂ could complement graphene and find its unique applications in flexible electronics, high temperature and radiation hard electric and opto-electric devices. There have been several efforts in fabricating single layer (SL) MoS₂ using mechanical exfoliation method but found a low value of mobility on SiO₂ substrates typically 0.01˜10 cm²V⁻¹s⁻¹. Wang et al. studied mechanically exfoliated MoS₂ on SiO₂ and found the room temperature mobility of ˜10 cm²V⁻¹s⁻¹ for bilayer FETs, which are substantially lower than the measured 200 cm²V⁻¹s⁻¹ of the bulk MoS₂. The very low mobility is believed to be due to the charge disorder caused by unwanted chemical bonding and/or roughness at the interfaces. However the use of other gate dielectric materials likes HfO₂, Al₂O₃ by several research groups had demonstrated a much higher mobility values. But, the complicated process of exfoliating single-layer MoS₂ with an additional high-k dielectric layer may significantly limit its compatibility with commercial fabrication. Besides, the traditional mechanical exfoliation method lacks in the formation of large scale SL and few layers MoS₂ films limiting its use for widespread applications. Therefore, the large-scale synthesis of high-quality single or a few layers MoS₂ is still a challenge.

For synthesizing large area MoS₂ thin films, several research groups attempted a wide range of methods including thermal evaporation, van der Waal epitaxy (VDWE), sputtering, pulsed laser deposition (PLD), and electron beam evaporation (EBE). However, most of these techniques have been reported to produce MoS₂ in morphologies other than layered (e.g. nano particles, nanorods and nanotubes). This is mainly due the fact that such approaches produce many nucleation sites and the resultant film growth is initiated from these sites. Techniques like VDWE and molecular beam epitaxy (MBE), at very low vacuum and controlled deposition rates can produce ordered 2D layered structures, but they are rather expensive. Other methods have been studied to produce MoS₂ including liquid phase deposition, liquid exfoliation, laser thinning, solid state reactions and hydrothermal methods but they take several preparation processes and are useful only for the production of composites and hybrid dispersions. So far, chemical vapor deposition has been demonstrated as the most practical method of synthesizing large-area and high quality graphene, boron nitride, and 2D TMDs nanosheets. A direct growth of MoS₂ monolayers can be achieved on various substrates by using the vapour-phase reaction of MoO₃ and S powders in a CVD system. Najmaei et. al. synthesized MoS₂ atomic layers on Si/SiO₂ substrates by using this method and reported an average mobility and maximum current on/off ratio of 4.3 cm²V⁻¹s⁻¹ and ˜10⁶, respectively. However, the main concern of this method is the formation of MoS₂ monolayer crystal flakes on the substrates rather than the formation of a continuous MoS₂ layer and sometimes the reaction normally leads to MoS₂ nanoparticles or nanorod structures with formation of by products like MoO₂ during the synthesis. Zhan et al. grew large area MoS₂ films e-beam evaporation and CVD methods and found a p-type conduction but with very poor mobility in the range of 0.004-0.04 cm²V⁻¹s⁻¹. Recently, Yu et al. developed a new method that precisely control the number of MoS₂ layers over a large area by using MoC₁₅ and sulfur as precursor materials in a CVD at high temperature. But the field-effect mobility of charge carriers in their device was found to be very low (0.003-0.03 cm²V⁻¹s⁻¹). Furthermore the thickness modulated growth of MoS₂ thin layered structure has not been reported yet. In considering the theoretical estimation that the energy bandgap change of MoS₂ with thickness, it is therefore imperative to develop suitable deposition method for the growth of thickness modulated films while demonstrating high quality, uniform and continuous films over a large area exhibiting excellent electrical properties.

The present invention provides a simple and scalable two step sputtering-CVD reaction approach that can produce high quality, large scale and thickness modulated MoS₂ atomic layers over a large area (˜2 inches) of Si/SiO₂ substrate. Mo thin film thickness was varied by changing magnetron sputtering time to modulate the thickness of MoS₂ film via sulfurization. The presence of single layers over an area of 2″ wafer was confirmed by Raman mapping (mapping area of 10-15 μm²) AFM and HRTEM images. Electrical measurements demonstrated a p-type semiconductor behavior with significantly high mobility and Ion/off ratio as compared to exfoliated and other CVD grown MoS₂ films on silicon substrates. This method is compatible to conventional semiconductor process and can be extended to other TMDs and arbitrary substrates by transferring MoS₂ layers including flexible substrates for flexible electronic applications.

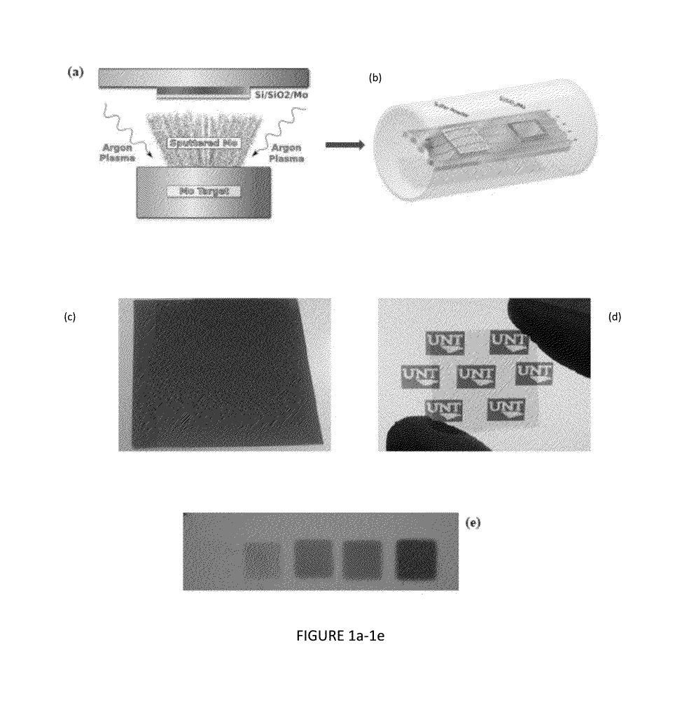

FIG. 1a is an image of the first step of sputtering followed by the second step of CVD method for the growth of MoS₂ thin films seen in FIG. 1b. FIG. 1c is an optical images of large area MoS₂ growth on a Si/SiO₂ substrate and FIG. 1d is an optical images of large area MoS₂ growth on a transparent substrate. FIG. 1e is an image showing the Optical contrast of MoS₂ films at for sample S1-S5 shows different thicknesses.

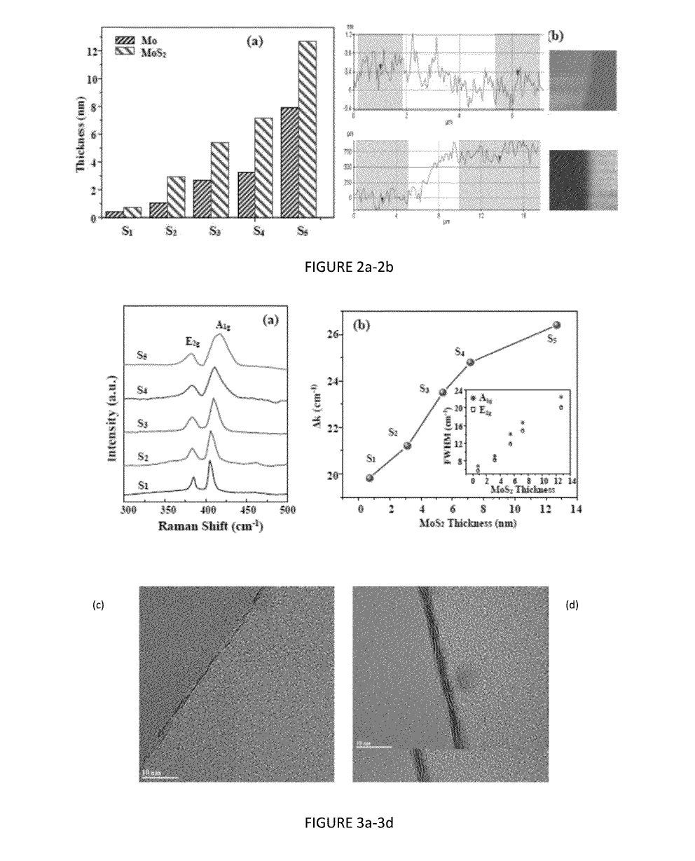

FIG. 2a is a graph of Mo and MoS₂ film thickness for sample S1-S5. FIG. 2a is an image of the AFM height profiles and images of a Mo and MoS₂ film on a Si/SiO₂ substrate of sample S1. The number of atomic layers in MoS₂ thin films can be identified from measuring the thickness by atomic force microscope (AFM). FIG. 2a shows the thickness bar chart for Mo and MoS₂ thin films corresponding to samples S1-S5. The thickness of MoS₂ films as estimated by AFM height profiles was found to be 0.72, 3.01, 5.40, 7.16 and 12.69 nm corresponding to sample S1, S2, S3, S4 and S5, respectively. The cross sectional height in FIG. 2b reveals that the thickness of MoS₂ film for sample S1 is −0.72 nm, which typically corresponds to one atomic layer of MoS₂ based on previous reports for a monolayer MoS₂ on Si/SiO₂ substrate. It is now well known that the difference between the in-plane (E¹_{2g}) and out-of-plane (A_{1g}) Raman modes (Δk) is an appropriate quantity to assign the number of MoS₂ layers on a variety of substrates.

FIG. 3a is an image of the Raman spectra of MoS₂ thin films corresponding to sample S1, S2, S3, S4 and S5. FIG. 3a shows the Raman spectra of MoS₂ films with different thicknesses, measured at 532 nm excitation laser line. For sample S1, the two Raman characteristic bands at 405.2 and 385.5 cm⁻¹ corresponding to A_{1g} and E¹_{2g} vibration modes shows a peak frequency difference of 19.7 cm⁻¹ which evidences the existence of monolayer MoS₂. The higher value of Δk as compared to their exfoliated counterparts could be related to crystalline imperfection due to smaller crystalline grains in the synthesized thin film. FIG. 3b is an image of the difference between the in-plane (E¹_{2g}) and out-of-plane (A_{1g}) Raman modes (Δk) with increasing MoS₂ film thickness: Inset shows the raman peak FWHM of E¹_{2g} and A_{1g} modes. It is apparent from the raman spectra of samples S2-S5 that the E_{2g} and A_{1g} peaks shift apart from each other with increasing MoS₂ thickness which in turn increases the frequency difference (Δk) of the synthesized thin films (FIG. 3b), consistent with what were observed on exfoliated MoS₂. It is also worth noting that the full width at half maximum (FWHM) of the Raman peaks increases with increasing MoS₂ thickness as shown in the inset of FIG. 3b. FIG. 3c is a cross-sectional HRTEM image of sample S1. FIG. 3d is a cross-sectional HRTEM image of sample S2. The lower value of FWHM in case of sample S1 and S2 represents the high structural quality in our MoS₂ films. To further confirm the quality and number of MoS₂ layers, HRTEM was performed and FIGS. 3c and 3d shows the cross-section view MoS₂ layers on Si/SiO₂ substrates for sample S1 and S2, respectively. The thickness of MoS₂ layer extracted from HRTEM was found to be 0.69±0.02 nm for sample S1 confirms the formation of a monolayer while sample S2 shows a clear stacking of 3-4 MoS₂ layers. The results obtained by HRTEM are found in well agreement with AFM height profiles and Raman spectra.

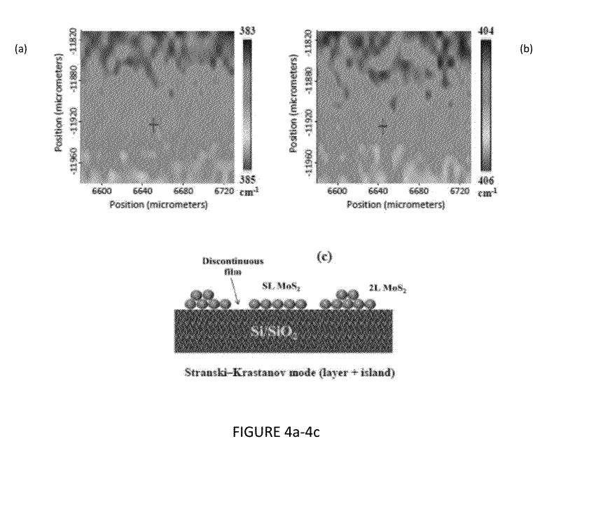

FIG. 4a is a Raman mapping images of E¹_{2g} frequencies for a 150 μm×150 μm area for sample S1. FIG. 4b is a Raman mapping images of A_{1g} frequencies for a 150 μm×150 μm area for sample S1. FIG. 4c is a schematic of layer and island growth mechanism in sputtered Mo films. It is difficult to obtain uniform SL MoS₂ over the entire substrate after sulfurization of deposited Mo films (S1) for the reasons stated in the introduction part of this manuscript. To ascertain the uniformity of SL MoS₂ for sample S1, Raman mapping of E¹_{2g} and A_{1g} frequencies was collected over a wide area of 150 μm×150 μm as shown in FIGS. 4a and 4b, respectively. We noted that the average peak spacing between E¹_{2g} and A_{1g} calculated from the areas marked as dotted circles was found to be ˜19.7 cm⁻¹ indicating the presence of monolayers while the areas shown in rectangles exhibits an average peak spacing of ˜21.2 cm⁻¹ represents approximately two layer of MoS₂. The thickness uniformity was also confirmed by AFM that the thickness of MoS₂ was in the range of 0.65-1.32 nm over the 2″ wafer. While the AFM height profiles for samples S2-S5 shows a uniform surface over the entire surface of the substrate with corresponding thickness values mentioned above. In addition, our results are consistent with the Raman mapping analysis of Lee and Zhan that shows a blue-shift for E¹_{2g} and red-shift for A_{1g} with decrease in MoS₂ film thickness. It is evident from the Raman mapping that uniform MoS₂ monolayers exists over an area of 10-15 μm², which is similar or larger size of SL MoS₂ grown by other methods The non-uniformity in monolayer for sample S1 could be attributed to the layer and island growth modes of Mo films on Si/SiO₂ substrates depending on the interaction energies of substrate atoms and film atoms as shown in FIG. 4c. It is also worth noting that HRTEM image for sample S1 (as shown in FIG. 3c) shows the formation of a discontinuous single layer MoS₂ film. The voids or discontinuity in SL MoS₂ layer could be due to very low deposition time for Mo atoms to reach substrate surface with sufficiently high energy.

FIG. 5a is a 3D view of the MoS₂ FET. After the growth and characterization of the MoS₂ films with different thicknesses on Si/SiO₂ substrates, their electrical properties were evaluated by fabricating MoS₂ field effect transistor (FET) devices with 50 nm thick Au as source and drain electrodes, 300 nm thick SiO₂ served as dielectric layer while doped silicon was used as the back gate. FIG. 5a shows the schematic view of the transistor. The electrical measurement on sample Si showed a very high resistance without any indication of FET behavior or gate biasing effect. It could be attributed to the large spatial constraints imposed by the substrates for very thin layers of MoS₂ film and discontinuity or voids formation for sample S1. It was observed that an increase in MoS₂ thickness up to 2.92 nm for sample S2 results in large area and uniform growth of 3-4 MoS₂ atomic layers exhibiting a good FET behavior with pronounced gate bias modulation.

FIG. 5b is a graph of the room-temperature output (I_{d}-V_{d}) characteristics for sample S2 as a function of gate bias V_{g} from 0 to −15V. FIG. 5b shows the typical output characteristics, i.e, drain current versus drain voltage (I_{d}-V_{d}) as a function of gate voltage varying from 0 to −15V. It is evident from the figure that I_{d}-V_{d} curve exhibits negligibly very low currents at zero gate voltage (V_{g}=0) while a significant increase in drain current was observed with increasing gate voltage upto −15V. FIG. 5c shows the dependence of drain current on the back-gate voltage (I_{d}-V_{g}) at drain-source voltage of 0.5V for sample S2. The repeated I_{d}-V_{g} sweep on the same device was not found to show any significant variation of the current showing that the fabricated devices are not affected by charge accumulation at the interfaces. However, the lack of drain current saturation in the transfer characteristics (I_{d}-V_{g}) of sample S2 could be attributed to the presence of thick SiO₂ back gate dielectric. It is worth to note that the transfer characteristic of sample S2 represents a p-type behavior differently from the naturally grown MoS₂ crystal that is n-type semiconductor.

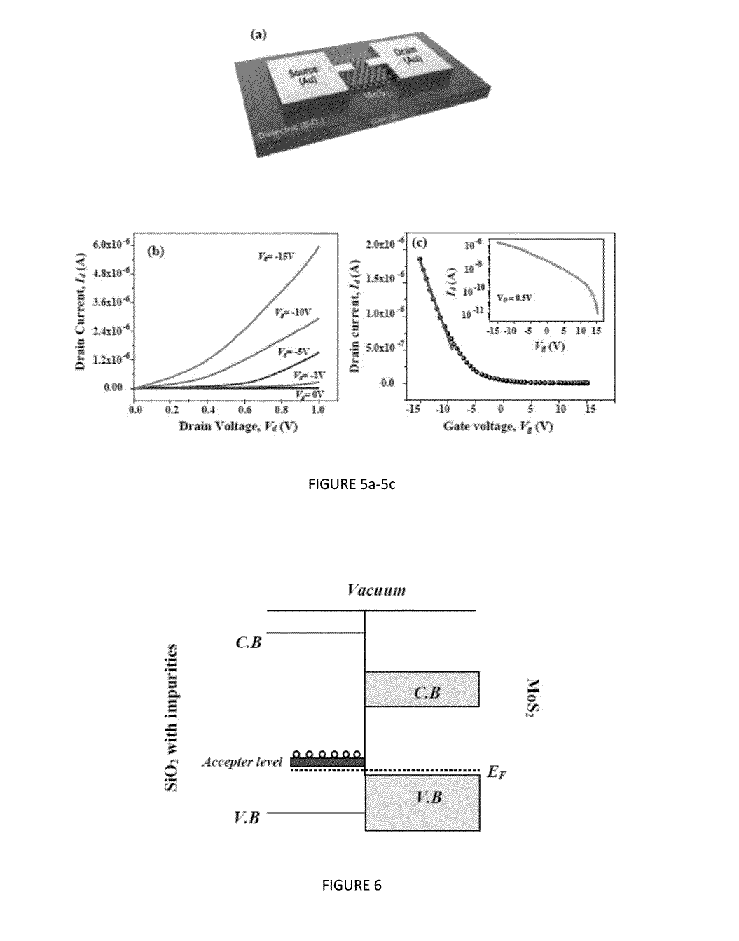

FIG. 6 is a schematic band diagram of SiO₂/MoS₂ interface showing the formation of acceptor level above Fermi level due to the presence of impurities, dangling bonds at the interface. The p-type behavior in our layered MoS₂ could be due to the presence of localized trap states which are expected to present at the interface of Si/SiO₂ substrate and MoS₂ film which tends to relocate the Fermi level of SiO₂/MoS₂ system just below the valence band maxima, making system a p-type semiconductor as schematically represented by FIG. 6. The trap states might have originated from the immobile ionic charges, SiO₂ surface oxygen dangling bonds or foreign impurities presented at SiO₂/MoS₂ interface during MoS₂ synthesis. There are several other reports showing the p-type conductivities in ultrathin MoS₂ layers deposited on SiO₂. Zhan et al. also reported a p-type behavior in CVD grown MoS₂ layers on Si/SiO₂ substrates. Zeng et al. fabricated single layer MoS₂ by lithiation process and observed a p-type doping on Si/SiO₂ substrate. The conducting behavior of MoS₂ therefore seems to depend on the experimental details and substrate conditions, hence more detailed experimental and theoretical studies should be done to understand the origin of current polarity (n- or p-type) in 2D MoS₂ thin films.

The drain current I_{d} for sample S2 was re-plotted on a logarithmic scale as a function of V_{g} (inset of FIG. 5c). At V_{g}=+15V, the MoS₂ channel of the FET was found to be pinched off with an OFF-state I_{d} ˜1.18×10⁻¹² A while the ON-state current I_{d} at V_{g}=−15V was approximately 1.86×10⁻⁶ A, yielding a corresponding current on/off ratio ˜1.57×106. The field-effect mobility of this FET was calculated by using the formula:

$$μ = ( \frac{L}{W {C}_{ox}} ) ( \frac{1}{{V}_{d}} \frac{Δ {I}_{d}}{Δ {V}_{d}} ) \qquad ( 1 )$$

where, ΔI_{d}/ΔV_{g} was determined from the slope of a linear-fit of the data from the I_{d}-V_{g} curve. VD: drain source voltage (0.5 V), L: gate length (10 μm), W: device width (30 μm), Cₒₓ=∈o∈r/d is the gate insulator capacitance, for SiO₂, ∈o=8.854×10⁻¹² F/m, ∈r=3.9, thickness of dielectric, d=300 nm. The field effect mobility was determined to be 12.64 cm²V⁻¹s⁻¹. The table below compares the Ion/off ratio and field effect mobility of our two-step grown MoS₂ device with previously reported mechanically exfoliated and CVD grown MoS₂ FETs on Si/SiO₂ substrates.

| | | Field effect | |
|---|---|---|---|
| S. | | mobility | ON/OFF |
| No. | Method | (cm²V⁻¹s⁻¹) | ratio |
| 1. | Sputtering-CVD | 12.64 | 1.56 × 10⁶ |
| 2. | CVD | 0.02 | ~10⁴ |
| 3. | CVD | 0.003-0.03 | ~10³ |
| 4. | Thermolysis | 6.0 | ~10⁶ |
| 5. | CVD | 4.3 | 6.0 × 10⁶ |
| 6. | Exfoliated | 1.5 | ~10² |
| 7. | Exfoliated | 3.0 | — |
| 8. | e-beam-CVD | 0.004-0.04 | — |
| 9. | CVD | 0.03-0.23 | ~10⁵ |
| 10. | Exfoliated | 0.1-10 | 1 × 10⁶ |
| 11. | Exfoliated | 10-15 | 10⁷ |
| 12. | CVD | 17 | 10⁸ |

A significant improvement in the transistor parameters can be noticed in our p-type MoS₂ FETs as compared to other research groups. Also the field effect mobility in our MoS₂ FETs is much higher than the commercially available thin film FETs based on amorphous silicon (a-Si) and organic materials. A similar behavior of the output (I_{d}-V_{d}) and transfer (I_{d}-V_{g}) characteristics exhibiting p-type conduction was observed for sample S3. The value of I_{on/off} ratio and field effect mobility for sample S3 were found to be 5.7×10⁴ and 0.47 cm²V⁻¹s⁻¹, respectively. With further increase in MoS₂ film thickness for sample S4 (7.16 nm) and S5 (12.69 nm), a significant drop in MoS₂ resistance showing a metallic type behavior was observed in the FET characterization. We believe that 100% Mo was not converted to MoS₂ during sulfurization at higher thickness of Mo films. The theoretical MoS₂ thickness that could be obtained by complete sulfurization of Mo films corresponding to S1, S2, S3, S4 and S5 was characterized to be 1.11, 4.18, 6.44, 14.11 and 34.99 nm, respectively. It can be observed that the theoretical and experimental values of MoS₂ thickness were same up to sample S3, but there was a large deviation when Mo film thickness increases for sample S4 and S5 that could be attributed to the partial sulfurization of Mo at higher thicknesses.

The present invention provides fabricating large-area, thickness-modulated MoS₂, varying from single to few layer MoS₂ films on Si/SiO₂ substrates using a combination of magnetron sputtering followed by chemical vapor deposition. Raman spectra, AFM height measurement data and HRTEM images demonstrated the presence of single layer MoS₂ over an area of 2 inch with the domain size of 10-20 μm². The electric measurement for the bottom-gate transistor shows a dominant p-type semiconductor behavior with the high current on/off ratio of 1.57×10⁶ and a high field effect mobility of 12.64 cm²V⁻¹s⁻¹. Our results demonstrated an important step towards device fabrication with controlled MoS₂ synthesis. These results suggest that large area growth of MoS₂ atomic layers with p-type conduction would increase the compatibility and integration of these TMDs in current nano and micro p-FET applications and also open avenues in flexible and high temperature radiation hard electronic and optoelectronic devices.

FIGS. 1a and 1b illustrates the schematic diagram of our two step synthesis method which involves the deposition of Mo films with different thickness on Si/SiO₂ substrates using magnetron sputtering followed by their sulphurization in a CVD chamber. First step involves the synthesis of Mo thin films on (100) oriented N-type (As doped, resistivity <0.005 Ω·cm) silicon substrates coated with 300 nm thick SiO₂ layer. The deposition time was varied from 4 sec to 180 sec to obtain a batch of Mo films with increasing thicknesses. High purity (99.99%) Mo metal target of 50 mm diameter was used for sputtering Mo thin films. The substrates were initially cleaned thoroughly with acetone in ultrasonic bath followed by cleaning in ethanol, methanol and DI water. The substrates were fixed on the heater and chamber was evacuated to a vacuum level of 10⁻⁷ Torr. Before every sputtering run, the target was pre-sputtered for 5 min to ascertain the same state of Mo target for each sample. In second step, magnetron sputtered Si/SiO₂/Mo films were subsequently placed in a low pressure chemical vapor deposition (LPCVD) system (Graphene Square CVD) equipped with a 4-inch diameter quartz tube furnace. A ceramic boat containing pure sulphur (˜1 gm, Sigma Aldrich) was placed in the upstream of quartz tube. Argon was used as a carrier gas to convey sulphur vapor species to the downstream Mo films. The tube was pumped down to a pressure of 10⁻³ Torr and flushed with Ar gas repeatedly to guarantee a favorable growth atmosphere. In the flow atmosphere of 200 sccm Ar with a chamber pressure of 5 Torr, the furnace was heated to 600° C. at the center zone in 30 minutes. After 60 minutes, the furnace was cooled down naturally to room temperature. The typical growth parameters for Mo and MoS₂ films are depicted below:

technique

| Parameters | Sputtering | CVD |
|---|---|---|
| Substrate | Si/SiO₂ | Si/SiO₂/Mo |
| Deposition material | Mo | Sulphurization |
| Deposition time | 2, 4, 10, 30, | 1 hr |
| | 60, 180 sec | |
| Deposition pressure | 10 mTorr | 5 Torr |
| Power | 60 W | — |
| Temperature | Room Temp | 600° C. |

The samples S1, S2, S3, S4 and S5 corresponds to MoS₂ films converted for Mo films deposited at different sputtering time of 4, 10, 30, 60 and 180 sec, respectively. Generally, the deposit time may be any time 1-180 seconds for sputtering and from 5 minutes to 1 hour for CVD. Similarly for CVD the deposition pressure may be varied from 1-100 Torr and temperatures of between about room temperature −800° C.

The height measurement of Mo and MoS₂ films was performed by an AFM (Parks NX-10) system. Raman spectra of MoS₂ thin films were collected in Almega XR Raman spectrometer equipped with an Olympus BX51 microscope with motorized stage, mapping capabilities, and spatial resolution down to 1 um and the wavelength of laser is 532 nm. The MoS₂ films were characterized by TECNAI F20 S-Twin (FEI Co, Netherland) Transmission Electron Microscope (TEM) operating at an accelerating voltage of 120 kV equipped with Energy Dispersive Spectroscopy (EDS). The cross section of TEM sample was lifted-out with Quanta 3D dual-Focused Ion Beam (FIB) on the Mo half grid for quantitative EDS analysis. The electrical measurements were performed at room temperature using an Agilent B2912A precision source/measure unit (2 ch, 10 fA, 210V, 3A DC/10.5A Pulse) connected to a probe station with 20 μm size tungsten probes. All electrical measurements on MoS₂ devices were performed in vacuum in order to isolate the effect of ambient oxygen and water. FIGS. 1c and 1d shows optical microscope images of uniform and large scale growth of MoS₂ films with various thicknesses. FIG. 1e shows the optical images of MoS₂ films with different thickness (S1-S5) grown on a transparent quartz substrate. The optical contrast in different samples clearly shows the variation in MoS₂ thickness. Mo film of any thickness can be directly grown or transferred to any transparent or flexible substrates. The high transparency in MoS₂ films shows their potential to be used in future transparent and flexible electronics.

This method is compatible to conventional semiconductor process and can be extended to other 2D materials and arbitrary substrates by transferring MoS₂ layers including flexible substrates for flexible electronic applications. The polarity of MoS₂ can be modulated by introducing surface functionality of substrate oxygen terminated surface for p-type semiconductor and K, Cl, Na for n-type semiconductor. The developed film can be extended to design novel devices such as field effect transistors (FETs), optical switch, flexible electronics, and lubricant coating. The 2D materials known as Transition metal dichalcogenides (TMDCs) are the group of hexagonal structured, van der Waals bonded, layered materials with the molecular formula MX₂ (where M=transition metals such as Mo, W, Nb, and X=chalcogens such as S, Se, Te). The TMDC materials exhibit strong in-plane bonding along with weak out-of-plane bonding, enabling the exfoliation of the materials into single crystal two-dimensional flakes with atomic level thickness. It has emerged recently that there are over 40 exotic layered materials which can be split into a single atom thick material, including molybdenum disulfide (MoS₂), molybdenum disilicide (MoSe₂), silicene, boron nitride (BN), tungsten disulfide (WS₂), WSe₂, germanene etc., and their hybrid-structures. Looking at these materials very closely, we observe that the consequences of their extraordinary properties are more dimension-dependent than size-dependent, hence creating a new area for research. Depending on their chemical composition and structural configurations, atomically thin 2-D materials can be metallic, semi-metallic, or semiconducting. In particular, some of the TMDC materials and their heterostructures have shown remarkable electronic and optoelectronic properties. For example, monolayer MoS₂ exhibits a direct intrinsic bandgap (˜1.8 eV), acceptable mobility for transistor operation (˜200 cm²V⁻¹s⁻¹), and quantum confinement. In this context, the intrinsic semiconducting property of the 2-D MoS₂ structure is advantageous, since there is no need for doping or making super-narrow ribbons, as would be required to create a comparable energy band gap in graphene. Therefore, even at room temperature, 2-D MoS₂ based field effect transistors exhibit high current on/off ratios of 1×10⁸ and ultra-low power dissipation, which will be highly advantageous for future electronics and opto-electronics.

As stated above, FIGS. 1(a) and 1(b) illustrates the schematic diagram of our two step synthesis method which involves the deposition of Mo films with different thickness on Si/SiO₂ substrates using magnetron sputtering followed by their sulphurization in a CVD chamber. First step involves the synthesis of Mo thin films on substrates. The substrates were initially cleaned thoroughly with acetone in ultrasonic bath followed by cleaning in ethanol, methanol and DI water. For sputtering Mo films, a high frequency power supply (RF power supply) creating 13.56 MHz plasma for thin film deposition was used. The substrate was fixed on a heater with the help of clips for the fabrication of thin films. The temperature of the substrate was kept from room temperature to 800° C. for whole batch of samples. After mounting the substrates, the chamber was evacuated using a turbo molecular pump, backed by a rotary pump up to a high vacuum (≦2×10⁶ Torr). After evacuation, an inert gas like Argon was fed into the chamber via gas inlet valve. Simultaneously, the gate valve was brought into an almost closed state (throttling) so as to match the gas influx and pumping-out rate. With proper throttling, the inert gas pressure and flow rate inside the chamber can be made very stable. Sputtering of Mo target starts when a RF power (60 W) is applied to the target material that is at a negative potential with respect to the substrate (anode), causing a plasma or glow discharge. Positive charged gas ions generated in the plasma region are attracted to the negatively biased target plate at a very high speed. This collision creates a momentum transfer and ejects atomic size particles from the target. These particles are deposited as a thin film into the surface of the target substrates. Substrate holder was rotated axially at 2 rpm to achieve a uniform film composition. The flow rate of argon gas was controlled by MKS (model 247) mass flow controllers. The target to substrate distance was fixed at approximately 7 cm for Mo films. The deposition time was varied from 4 sec to 180 sec to obtain a batch of Mo films with increasing thicknesses.

In second step, magnetron sputtered specimen were subsequently placed in a low pressure chemical vapor deposition (LPCVD) system. A ceramic boat containing pure sulphur (˜1 gm, Sigma Aldrich) was placed in the upstream of quartz tube. Argon was used as a carrier gas to convey sulphur vapor species to the downstream Mo films. The tube was pumped down to a pressure of 10⁻²-10⁻⁵ Torr and flushed with Ar gas repeatedly to guarantee a favorable growth atmosphere. In the flow atmosphere of 20-1,000 sccm Ar with a chamber pressure of 1-100 Torr, the furnace was heated to 300-800° C. at the center zone in 1-60 min. After CVD reaction, the furnace was cooled down naturally to room temperature.

The present invention also provides thickness dependent energy bandgap control. Band gap engineering of TMDs is crucial for their wide applications in nanoelectronics, optoelectronics, and photonics. The conversion of bulk TMDs into mono or few-layers by exfoliation, CVD, or any other method leads to additional characteristics due to confinement effects. One of the important effect arises from the quantum confinement is the transition of TMDs bandgap from an indirect to direct gap on going from a bulk to a monolayer.

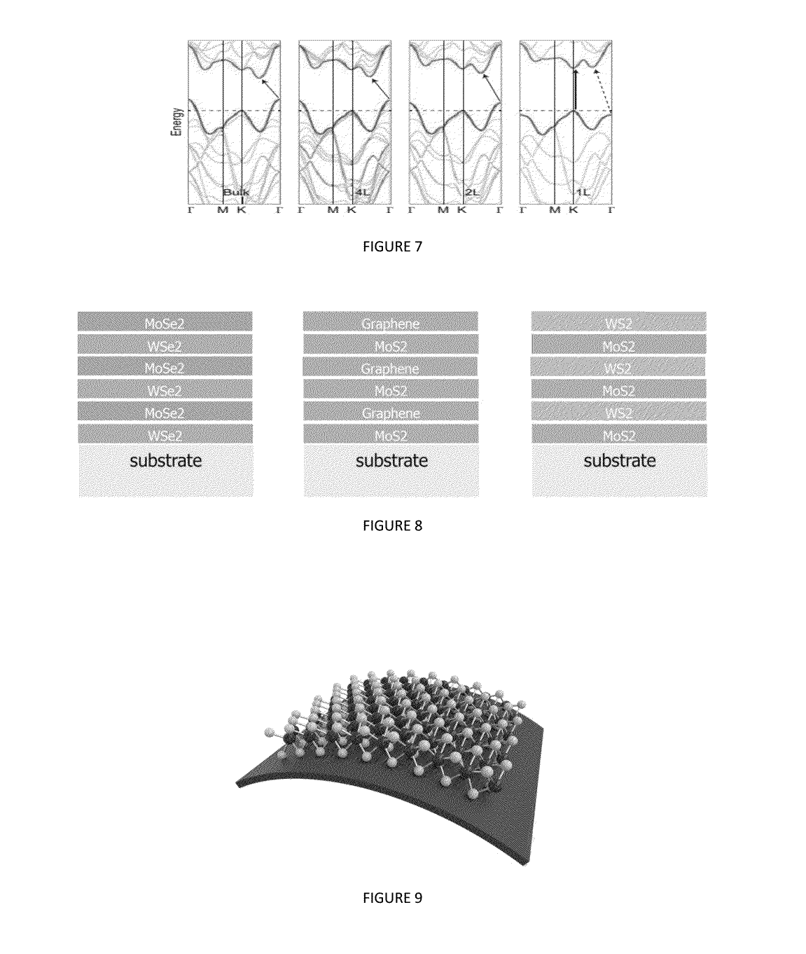

FIG. 7 shows the band gap variations from an indirect (bulk) to direct (SL) TMDs with decreasing thickness from bulk to few-to monolayer. It is clear from the figure that bulk material is an indirect gap semiconductor with a valence band maximum (VBM) at the F point and a conduction band minimum (CBM) at the midpoint along Γ-K symmetry lines. In contrast, an isolated monolayer of the same material is a direct-gap semiconductor with VBM and CBM coinciding at the K-point. Hence, our method enables us the band gap engineering based on controlling number of layers in TMDs. The number of layers can be controlled by metal deposition of Mo thin films as described in the above mentioned two-step methods.

In addition the present invention provides a method of modulating the polarity of MoS₂ by introducing surface functionality of substrate: oxygen terminated surface for p-type semiconductor and K, Cl, Na-terminated surface for n-type semiconductor. The surface of substrates is prepared by selection of oxide substrates or oxide coating (or oxygen plasma treatment) for p-type MoS₂ and the substrate is treated with one of the functional elements of K, Cl and Na for n-type MoS₂. The n-type functionalizing method can be either plasma surface treatment with introducing the elements mentioned above or chemical surface treatment with a chemical solution. In addition the present invention relates to devices such as field effect transistors, hetero junction devices, and tribology and lubricant coatings. Other devices include FETs (including FETs on flexible substrates for flexible electronics). Along with the development of large scale production of MoS₂ using our two-step sputtering CVD method, MoS₂ optical properties can be applied in MoS₂-based integrated optoelectronic circuits, light sensing, biomedical imaging and next-generation ultrathin electronic and optoelectronic devices. It is possible due to its unique properties of direct band gap (˜1.8 eV), good mobility (˜200 cm²V⁻¹s⁻¹) and quantum confinement, which results in high current on/off ratios of 1×10⁸ and ultra-low power dissipation in MoS₂ based field effect transistors (FETs), which are highly advantageous for future low power electronics. After transfer the film onto a flexible substrate, the MoS₂ based flexible electronic devices can be fabricated.

The large optical absorption (˜10⁷ m⁻¹ across the visible range) and gigantic PL arising from the quantum confinement effects in their monolayers that expands the bandgap from 1.2 eV to 1.9 eV with transition from indirect bandgap to direct bandgap. This strong PL of ultrathin MoS₂ implies several possible applications in optoelectronics such as high photo gain and fast optical switches. The photoresponsivity of MoS₂ photodetectors fabricated using single and multilayer MoS₂ is shown below. The capability of high-temperature operation would offer great advantages for future smart sensors working under harsh environmental conditions.

### Photoresponsivity of Different MoS₂ Photodetectors

| S. | | | |
|---|---|---|---|
| No. | Photodetectors | Photoresponsivity | |
| 1. | First MoS₂ single layer | 7.5 × 10⁻³ | A/W |
| 2. | Multilayer MoS₂ | 0.1 | A/W |
| 3. | few layer MoS₂ at | 0.57 | A/W |
| | 200° C. | | |
| 4. | Monolayer MoS₂ | 880 | A/W |

The present invention may be used in hetero junction devices. Assembling large scale MoS₂ with graphene and other 2D TMDs materials like WSe₂ will open new avenues in the field of hybrid field effect transistors and photovoltaic devices. For example, in a graphene/MoS₂ junction device, the large area MoS₂ with large bandgap will absorb the sunlight and the photo generated electrons and holes will be easily transferred across the graphene and MoS₂ junction and thereby producing a large photo response with high photo gain. On the other hand, stacking two or more TMDs will open new possibilities of tailoring electronic properties of TMD multilayer different from the homogenous monolayers. The different band gaps in individual TMD monolayers when stacked will open fields in band gap engineering. Multilayers of TMDs will be able to make rf switching devices, optical switch devices and solar cells.

FIG. 8 shows MoSe₂/WSe₂, MoS₂/graphene and MoS₂/WS₂ hetero junctions. During graphene/MoS₂ heterostructure preparation, graphene will be separately prepared on Cu foil using LPCVD methods and then copper will be etched away using Cu etchant. The free floating graphene will be transferred mechanically on the large area MoS₂ films deposited using our two step method described herein. On the other hand TMDs heterostructure may be prepared by Mo and W films being alternatively deposited using magnetron sputtering technique specially designed to fabricate multilayers utilizing two metal targets without breaking the vacuum in the system. The Mo/W multilayers will be kept in a CVD furnace followed by sulphurization or selenization at high temperature (600° C.).

Tribological coatings are intended to decrease the friction and wear of the materials so as to increase their life and performance. They are particularly important in the field of aerospace, tool industry, automotive and other where failure can be severe. The tribological properties of 2D transition metal dichalcogenide solid lubricant such as MX₂ (where M is molybdenum or tungsten and X is sulphur or selenium) are of technological interest for reducing wear in circumstances where liquid lubricants are impractical, such as in space technology, ultra-high vacuum or automotive transport, especially in the situations when fretting wear is present. In the 2D MoS₂ layered structure, a sheet of molybdenum atoms is sandwiched between two hexagonally packed sulphur layers. The bonding within the S-M-S sandwich is covalent, while weak Van Der Waals forces hold the sandwich together resulting in interlamellar mechanical weakness or low strength shearing. Thus, under a shearing force the basal planes slide over one another by intracrystalline slip and transfer to the rubbing counter face resulting in low friction. MoS₂ lubricant coatings can be deposited on any shape using our metal deposition-CVD process. FIG. 9 shows a large scale MoS₂ lubricant coating on curved surfaces, e.g., spherical or cylindrical objects.

It is contemplated that any embodiment discussed in this specification can be implemented with respect to any method, kit, reagent, or composition of the invention, and vice versa. Furthermore, compositions of the invention can be used to achieve methods of the invention.

It will be understood that particular embodiments described herein are shown by way of illustration and not as limitations of the invention. The principal features of this invention can be employed in various embodiments without departing from the scope of the invention. Those skilled in the art will recognize, or be able to ascertain using no more than routine experimentation, numerous equivalents to the specific procedures described herein. Such equivalents are considered to be within the scope of this invention and are covered by the claims.

All publications and patent applications mentioned in the specification are indicative of the level of skill of those skilled in the art to which this invention pertains. All publications and patent applications are herein incorporated by reference to the same extent as if each individual publication or patent application was specifically and individually indicated to be incorporated by reference.

The use of the word “a” or “an” when used in conjunction with the term “comprising” in the claims and/or the specification may mean “one,” but it is also consistent with the meaning of “one or more,” “at least one,” and “one or more than one.” The use of the term “or” in the claims is used to mean “and/or” unless explicitly indicated to refer to alternatives only or the alternatives are mutually exclusive, although the disclosure supports a definition that refers to only alternatives and “and/or.” Throughout this application, the term “about” is used to indicate that a value includes the inherent variation of error for the device, the method being employed to determine the value, or the variation that exists among the study subjects.

As used in this specification and claim(s), the words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps. In embodiments of any of the compositions and methods provided herein, “comprising” may be replaced with “consisting essentially of” or “consisting of”. As used herein, the phrase “consisting essentially of” requires the specified integer(s) or steps as well as those that do not materially affect the character or function of the claimed invention. As used herein, the term “consisting” is used to indicate the presence of the recited integer (e.g., a feature, an element, a characteristic, a property, a method/process step or a limitation) or group of integers (e.g., feature(s), element(s), characteristic(s), propertie(s), method/process steps or limitation(s)) only.

The term “or combinations thereof” as used herein refers to all permutations and combinations of the listed items preceding the term. For example, “A, B, C, or combinations thereof′ is intended to include at least one of: A, B, C, AB, AC, BC, or ABC, and if order is important in a particular context, also BA, CA, CB, CBA, BCA, ACB, BAC, or CAB. Continuing with this example, expressly included are combinations that contain repeats of one or more item or term, such as BB, AAA, AB, BBC, AAABCCCC, CBBAAA, CABABB, and so forth. The skilled artisan will understand that typically there is no limit on the number of items or terms in any combination, unless otherwise apparent from the context.

As used herein, words of approximation such as, without limitation, “about”, “substantial” or “substantially” refers to a condition that when so modified is understood to not necessarily be absolute or perfect but would be considered close enough to those of ordinary skill in the art to warrant designating the condition as being present. The extent to which the description may vary will depend on how great a change can be instituted and still have one of ordinary skilled in the art recognize the modified feature as still having the required characteristics and capabilities of the unmodified feature. In general, but subject to the preceding discussion, a numerical value herein that is modified by a word of approximation such as “about” may vary from the stated value by at least ±1, 2, 3, 4, 5, 6, 7, 10, 12 or 15%.

All of the compositions and/or methods disclosed and claimed herein can be made and executed without undue experimentation in light of the present disclosure. While the compositions and methods of this invention have been described in terms of preferred embodiments, it will be apparent to those of skill in the art that variations may be applied to the compositions and/or methods and in the steps or in the sequence of steps of the method described herein without departing from the concept, spirit and scope of the invention. All such similar substitutes and modifications apparent to those skilled in the art are deemed to be within the spirit, scope and concept of the invention as defined by the appended claims.

What is claimed is:

1. A method of making a thin layer MoS₂ on a substrate comprising the steps of:
providing a substrate;
providing a Molybdenum source;
using a magnetron to induce a plasma to generate Molybdenum ions from the Molybdenum source;
sputtering the Molybdenum ions on the substrate to form a thin layer of Molybdenum;
placing the substrate in a CVD chamber;
providing a sulphur source;
forming a sulphur vapor from the sulphur source, wherein the sulphur vapor is in communication with the CVD chamber; and
sulphurizing the thin layer of Molybdenum to form a thin layer of Molybdenum disulfide MoS₂.

2. A method of making a thin layer transition metal dichalcogenide (MX₂) on a substrate comprising the steps of:
providing a substrate;
providing a transition metal source;
using a magnetron to induce a plasma to generate transition metal ions;
sputtering the transition metal ions on the substrate to form a thin layer of transition metal;
placing the substrate in a CVD chamber;
providing a chalcogen source;
forming a chalcogen vapor from the chalcogen source in communication with the CVD chamber; and
contacting the chalcogen vapor with the thin layer of transition metal to form a thin layer transition metal dichalcogenide (MX₂).

3. The method of claim 2, wherein the transition metal is Mo, W, or Nb.

4. The method of claim 2, wherein the chalcogen is S, Se, or Te.

5. The method of claim 2, wherein the transition metal dichalcogenide is MoS₂, MoSe₂, MoTe, WS₂, WSe₂, WTe, NbS₂, NbSe₂, or NbTe.

6. The method of claim 2, wherein the thin layer of transition metal is 1, 2, 3, 4, 5, 6, 7, 8, 9, 10, 11, 12, 13, 14, 15, 16, 17, 18, 19, 20, 21, 22, 23, 24, 25, 26, 27, 28, 29, 30 or more layers thick.

7. The method of claim 2, wherein the transition metal dichalcogenide is 1, 2, 3, 4, 5, 6, 7, 8, 9, 10, 11, 12, 13, 14, 15, 16, 17, 18, 19, 20, 21, 22, 23, 24, 25, 26, 27, 28, 29, 30 or more layers thick.

8. The method of claim 2, further comprising the step of controlling one or more parameters of the magnetron to apply 2, 3, 4, 5, 6, 7, 8, 9, 10, 11, 12, 13, 14, 15, 16, 17, 18, 19, 20, 21, 22, 23, 24, 25, 26, 27, 28, 29, 30 or more layers of the transition metal.

9. The method of claim 2, further comprising the step of adding a second transition metal to form a second thin layer on the thin layer.

10. The method of claim 9, wherein the second transition metal is Mo, W, or Nb.

11. The method of claim 2, wherein the substrate is a Si/SiO₂ substrate.

12. The method of claim 2, wherein the magnetron uses a RF power source to creating a plasma.

13. The method of claim 2, wherein the temperature of the substrate is at a temperature of between room temperature −800° C.

14. The thin layer transition metal dichalcogenide (MX₂) coated substrate made by the process of claim 2.

15. A method of controlling the thickness of a thickness dependent energy bandgap controlled thin layer transition metal dichalcogenide (MX₂) on a substrate comprising the steps of:
providing a substrate;
providing a transition metal source;
providing a magnetron to induce a plasma;
generating transition metal ions from the transition metal source using the plasma;
sputtering the transition metal ions on the substrate to form a thin layer of transition metal;
controlling transition metal thickness by controlling a deposition time and a deposition temperature;
placing the substrate in a CVD chamber;
providing a chalcogen source;
forming a chalcogen vapor from the chalcogen source in communication with the CVD chamber; and
contacting the chalcogen vapor with the thin layer of transition metal to form a thin layer of transition metal dichalcogenide.

16. The method of claim 15, wherein the deposition time is between 4 sec and 5 min and the deposition temperature is between room temperature and 800° C.

17. The method of claim 15, wherein the transition metal is Mo, W, or Nb and the chalcogen is S, Se, or Te.

18. A method of forming a thin film field effect transistor (FET) device, comprising:
providing a silicon-on-insulator substrate;
etching a single crystal silicon thin film layer on an insulating thin film layer of the silicon-on-insulator substrate, wherein the etched single crystal silicon thin film layer is used as a channel;
forming a gate insulating layer on the silicon-on-insulator substrate that has the single crystal silicon channel formed thereon; and
forming a gate electrode, a drain electrode, and a source electrode by providing a substrate;
providing a transition metal source;
inducing a plasma using a magnetron;
generating transition metal ions using the plasma;
sputtering the transition metal ions on the substrate to form a thin layer of transition metal;
placing the substrate in a CVD chamber;
providing a chalcogen source;
forming a chalcogen vapor in communication with the CVD chamber; and
contacting the chalcogen vapor with the thin layer of transition metal to form a thin layer of transition metal dichalcogenide (MX₂).

19. The method of claim 18, wherein the transition metal (M) is Mo, W, or Nb and the chalcogen (X₂) is S, Se, or Te.

20. The method of claim 19, wherein the transition metal dichalcogenide is MoS₂, MoSe₂, MoTe, WS₂, WSe₂, WTe, NbS₂, NbSe₂, or NbTe.

21. The thin film field effect transistor (FET) device made by the process of claim 20.
